(19) United States
(12) Patent Application Publication
(10) Pub. No.: US 2026/0221961 A1
(43) Pub. Date: Jul. 30, 2026

(54) LOW VOLTAGE COMPARATOR WITH PROGRAMMABLE DEVICES TO IMPROVE INPUT DYNAMIC RANGE

(71) Applicant: QUALCOMM Incorporated, San Diego, CA (US)

(72) Inventors: Tigran MELIKYAN, Carrigaline (IE); Hayk REVAZYAN, Cobh (IE); Ashwin SETHURAM, San Clemente, CA (US)

(21) Appl. No.: 19/040,166

(22) Filed: Jan. 29, 2025

(51) Int. Cl. H03K 5/24

(52) U.S. Cl. CPC H03K 5/2481

(57) ABSTRACT

Certain aspects of the present disclosure are directed towards a comparator and techniques for signal comparison. An example comparator generally includes: a first input transistor path including a first input transistor with a gate coupled to a first input node of the comparator; a second input transistor path including a second input transistor with a gate coupled to a second input node of the comparator; a third input transistor path in parallel with the first input transistor path and including a third input transistor with a gate coupled to the first input node; and a fourth input transistor path in parallel with the second input transistor path and including a fourth input transistor with a gate coupled to the second input node.

### TECHNICAL FIELD

Certain aspects of the present disclosure generally relate to electronic devices and, more particularly, to a comparator with improved input dynamic range.

### BACKGROUND

A comparator is an electronic component that compares two input voltages and outputs a digital signal. The digital signal may indicate which of the two input voltages is higher. A comparator may be designed with high gain so that the comparator's digital output signal can quickly switch between logic states based on comparing the two input voltages. Comparators are widely used for various applications, such as zero-crossing detectors, pulse-width modulation (PWM) generation circuits, analog-to-digital converters, and calibration circuits. Unlike operational amplifiers designed for linear amplification (e.g., using transistors in a linear region of operation), a comparator may be designed for switching behavior with transistors operating in a saturation region.

### SUMMARY

The systems, methods, and devices of the disclosure each have several aspects, no single one of which is solely responsible for its desirable attributes. Without limiting the scope of this disclosure as expressed by the claims that follow, some features will now be discussed briefly. After considering this discussion, and particularly after reading the section entitled “Detailed Description,” one will understand how the features of this disclosure provide the advantages described herein.

Certain aspects of the present disclosure are directed towards a comparator. The comparator generally includes: a first input transistor path including a first input transistor with a gate coupled to a first input node of the comparator; a second input transistor path including a second input transistor with a gate coupled to a second input node of the comparator; a third input transistor path in parallel with the first input transistor path and including a third input transistor with a gate coupled to the first input node; and a fourth input transistor path in parallel with the second input transistor path and including a fourth input transistor with a gate coupled to the second input node.

Certain aspects of the present disclosure are directed towards a method for voltage comparison. The method generally includes: receiving a first input voltage at a gate of a first input transistor on a first input transistor path of a comparator; receiving a second input voltage at a gate of a second input transistor on a second input transistor path of the comparator; enabling or disabling a third input transistor path and a fourth input transistor path coupled in parallel with the first input transistor path and the second input transistor path, respectively, based on a configuration mode of operation of the comparator; and generating an output voltage based on comparison of the first input voltage and the second input voltage.

Certain aspects of the present disclosure are directed towards a calibration circuit. The calibration circuit generally includes a first multiplexer with a first input coupled to a first input node of the calibration circuit and a second input coupled to a second input node of the calibration circuit, a second multiplexer with a first input coupled to a first reference voltage node of the calibration circuit and a second input coupled to a second reference voltage node of the calibration circuit, and a comparator comprising: a first input transistor path including a first input transistor with a gate coupled to an output of the first multiplexer; a second input transistor path including a second input transistor with a gate coupled to an output of the second multiplexer; a third input transistor path in parallel with the first input transistor path and including a third input transistor with a gate coupled to the first input node; and a fourth input transistor path in parallel with the second input transistor path and including a fourth input transistor with a gate coupled to the second input node.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 illustrates an example device in which aspects of the present disclosure may be implemented.

FIG. 2 illustrates an example calibration circuit including a comparator that may be used for calibration of multiple inputs, in accordance with certain aspects of the present disclosure.

FIG. 3 illustrates an example comparator, in accordance with certain aspects of the present disclosure.

FIG. 4 is a flow diagram illustrating example operations for voltage comparison, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure are directed towards a configurable (e.g., programmable) comparator with increased input dynamic range as compared to some conventional implementations. For example, the comparator may include multiple parallel input transistor paths, multiple tail current paths, and multiple resistive load paths, where a subset of the parallel paths may be enabled or disabled based on a configuration mode of operation of the comparator. Different modes of operation may be associated with different input voltage levels, and the different paths may be enabled or disabled to support the input voltage levels, as described in more detail herein. In this manner, the comparator supports a wide input dynamic range (e.g., range of input voltages) while maintaining low power consumption compared to conventional implementations.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### An Example Device

It should be understood that aspects of the present disclosure may be used in a variety of applications. Although the present disclosure is not limited in this respect, the circuits disclosed herein may be used in any of various suitable apparatus, such as in the power supply, battery charging circuit, or power management circuit of a communication system, a video codec, audio equipment such as music players and microphones, a television, camera equipment, and test equipment such as an oscilloscope. Communication systems intended to be included within the scope of the present disclosure include, by way of example only, cellular radiotelephone communication systems, satellite communication systems, two-way radio communication systems, one-way pagers, two-way pagers, personal communication systems (PCSs), personal digital assistants (PDAs), Internet of Things (IoT) devices, and the like.

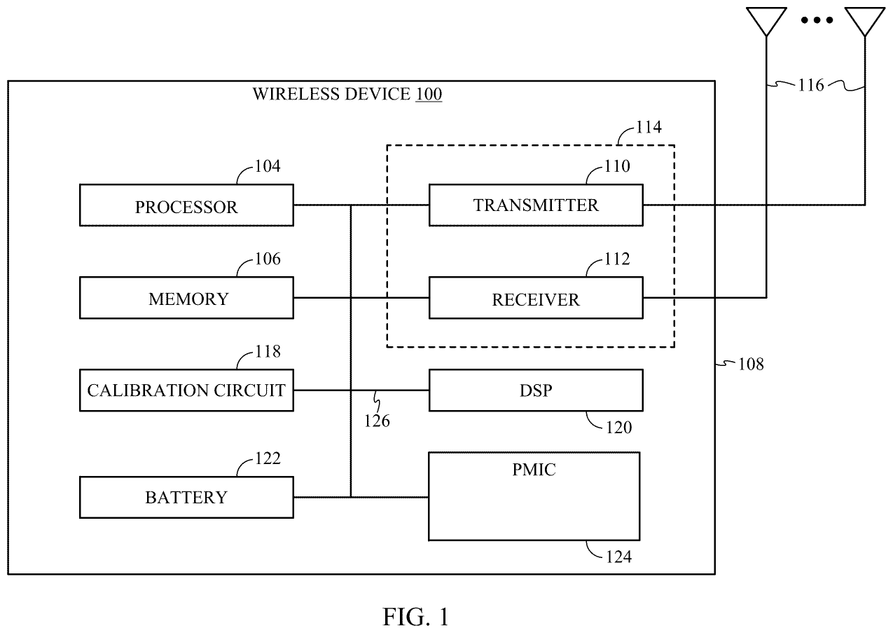

FIG. 1 illustrates an example device 100 in which aspects of the present disclosure may be implemented. The device 100 may be a battery-operated device such as a cellular phone, a PDA, a handheld device, a wireless device, a laptop computer, a tablet, a smartphone, an IoT device, a wearable device, an augmented reality device, etc.

The device 100 may include a processor 104 that controls operation of the device 100. The processor 104 may also be referred to as a central processing unit (CPU). Memory 106, which may include both read-only memory (ROM) and random access memory (RAM), provides instructions and data to the processor 104. A portion of the memory 106 may also include non-volatile random access memory (NVRAM). The processor 104 typically performs logical and arithmetic operations based on program instructions stored within the memory 106.

In certain aspects, the device 100 may also include a transmitter 110 and/or a receiver 112 to allow transmission and/or reception, respectively, of data between the device 100 and a remote location. In some cases, the transmitter 110 and receiver 112 may be combined into a transceiver 114. One or more antennas 116 may be attached or otherwise coupled to a housing 108 of the device 100 and electrically coupled to the transceiver 114. For certain aspects, the device 100 may include multiple transmitters, multiple receivers, and/or multiple transceivers (not shown).

The device 100 may also include a calibration circuit 118 that may be used to calibrate various inputs using a comparator with high input dynamic range, as described in more detail herein. The device 100 may also include a digital signal processor (DSP) 120 for use in processing digital signals.

The device 100 may further include a battery 122 used to power the various components of the device 100. The battery 122 illustrated in FIG. 1 may represent multiple portable power sources, such as a main battery and a backup battery (or a supercapacitor). In some cases, the battery 122 may be rechargeable.

The device 100 may also include a power management integrated circuit (PMIC) 124 (also referred to as a “power management unit (PMU)”) for managing the power from the battery 122 to the various components of the device 100, for example. In addition to managing power distribution, the PMIC 124 may perform a variety of other functions for the device, such as DC-to-DC conversion, battery charging, power-source selection, voltage scaling, power sequencing, etc.

The various components of the device 100 may be coupled together by a bus system 126. The bus system 126 may include a power bus, a control signal bus (e.g., system power management interface (SPMI) or inter-integrated circuit (I²C) bus), and/or a status signal bus in addition to a data bus.

### Example Comparator

Certain aspects of the present disclosure are directed towards a comparator with an improved input dynamic range. The present disclosure provides a low-voltage comparator with programmable input and tail devices and load resistive elements for improved input dynamic range. The comparator may be used for calibration and may be referred to as a “CAL comparator.” The comparator may be used to perform calibration for double data rate input/output (IO) (DDRIO) memory. In some aspects, the comparator may have a wide input dynamic range (e.g., an input voltage range of 200 mV to 500 mV) to support various modes of operations.

Some process technologies may not support thick gate devices. Therefore, using a high gain comparator from a core voltage supply while supporting dynamic voltage frequency scaling (DVFS) may be desirable to avoid electrical overstress issues. Designing a low-supply voltage comparator with high gain and low offset with a wide input dynamic range is challenging. In some aspects, bigger input transistors with lower thresholds and a lower tail current may be used for a low input voltage level. A smaller input transistor with a higher threshold and a higher tail current with less resistive load may be used for a higher input voltage level.

In some cases, the comparator may be implemented with programmability. For example, depending on an input voltage level to be supported for a particular mode of operation, low threshold voltage (V_{T}) input devices may be enabled or disabled, and in some cases, tail current source and parallel load resistive paths may be enabled or disabled. Certain aspects alleviate electrical overstress (EOS) issues as well as power and leakage concerns while meeting dynamic range specifications. The comparator described herein may be used for any suitable application that can take advantage of a wide input range comparator with a power-efficient design.

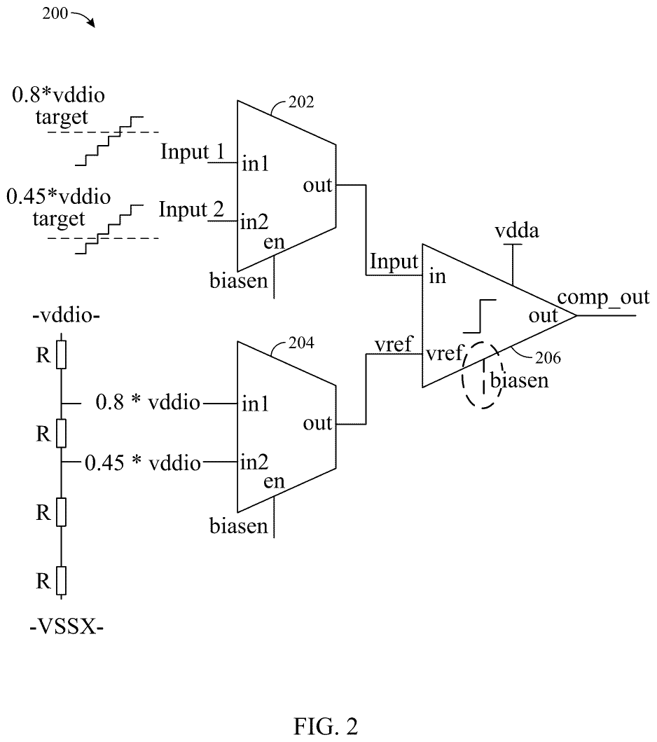

FIG. 2 illustrates an example calibration circuit 200 including a comparator 206 that may be used for calibration of multiple inputs, in accordance with certain aspects of the present disclosure. As shown, the circuit 200 may include a multiplexer 202 that may selectively provide, based on a bias enable (biasen) signal, a first input (Input 1) signal or a second input (Input 2) signal to an input of the comparator 206. The circuit 200 may also include a multiplexer 204 that may selectively provide, based on the biasen signal, a first reference voltage (e.g., 0.8× a supply voltage such as an IO supply voltage (vddio) or an analog supply voltage (vdda)) or a second reference voltage (e.g., 0.45×vddio or vdda) to a reference voltage (vref) input of the comparator 206. The first and second reference voltages may be generated using a resistive voltage divider, including resistive elements labeled “R” coupled between vddio and a reference potential node labeled “vssx”, although other techniques for generating the reference voltages may be used.

The comparator 206 may be used to calibrate the inputs. For example, the multiplexer 202 may provide a first input voltage to the input of comparator 206, and the multiplexer 204 may provide a first reference voltage to the vref input of the comparator 206. The first input voltage may be adjusted until the output (comp_out) signal of the comparator 206 transitions from one logic state to another logic state, based on which a circuit providing the first input voltage may be calibrated. For example, the first input voltage may be a bias voltage for a receiver circuit.

Similarly, the multiplexer 202 may provide a second input voltage to the input of comparator 206, and the multiplexer 204 may provide a second reference voltage to the vref input of the comparator 206. The second input voltage may be adjusted until the comp_out signal of the comparator 206 transitions from one logic state to another logic state, based on which a circuit providing the second input voltage may be calibrated. For example, the second input voltage may be generated using a pull-down circuit for a transmitter circuit. For instance, a series of transistors may be used to sink a current from a resistive element to generate the second input voltage. The resistance of the resistive element may be calibrated using the comp_out signal.

Some typical comparator implementations use a high-voltage supply with thick-gate devices to support a high dynamic range for calibrating multiple circuits. However, in some technology nodes, thick-gate devices may not be available, and the high voltage supply may cause high current leakage and power consumption (e.g., even during idle mode of the calibration circuit). The comparator 206 may use a relatively lower voltage supply (vdda) and support a wide input dynamic range using the biasen signal to dynamically configure the comparator 206 based on a configuration mode of operation. In this manner, the comparator 206 may be implemented without thick-gate devices, alleviates EOS concerns, and may be used to support power collapse scenarios for double data rate (DDR) memory. The comparator 206 may be used in any suitable interface to provide robust performance and compatibility with future technology nodes.

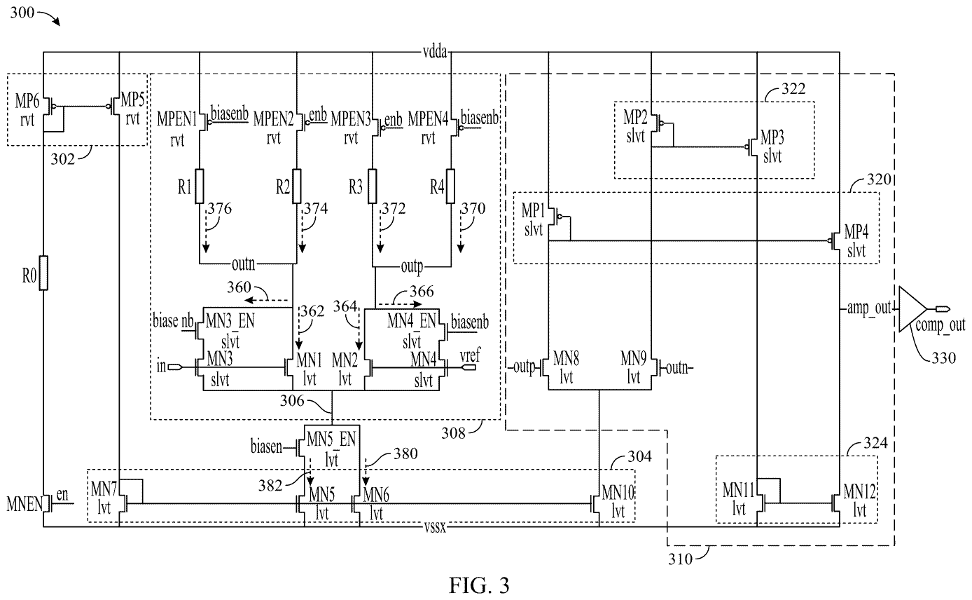

FIG. 3 illustrates an example comparator 300, in accordance with certain aspects of the present disclosure. The comparator 300 may correspond to the comparator 206 described with respect to FIG. 2.

The comparator 300 may include an enable circuit including an enable n-type metal-oxide-semiconductor (NMOS) transistor (MNEN). The transistor MNEN may be used to enable the comparator 300 using an enable (en) signal provided to the gate of the transistor MNEN. When enabled, the transistor MNEN may sink a current through a resistive element (R0) from a branch of a current mirror 302 formed by a p-type metal-oxide-semiconductor (PMOS) transistor MP6 and a PMOS transistor MP5. The PMOS transistor MP5 and MP6 may be regular voltage threshold (rvt) devices. As shown, to form the current mirror 302, the gate of MP6 may be coupled to a drain of MP6 and to a gate of transistor MP5. The sources of transistors MP5, MP6 may be coupled to the voltage rail (vdda). The enable circuit may also include a branch of a current mirror 304 formed by an NMOS transistor MN7 which may be a low voltage threshold (lvt) device. As used herein, an lvt device or transistor generally refers to a transistor with a lower threshold voltage than an rvt device or transistor.

The current mirror 304 may include another branch formed by an NMOS transistor MN5 (e.g., lvt device) of a tail current path 382 and another branch formed by an NMOS transistor MN6 (e.g., an lvt device) of a tail current path 380. The tail current path 380 may be in parallel with the tail current path 382. The transistors MN5 and MN6 may form tail current sources of an amplifier 308 for comparing an input voltage at an input node (labeled “in”) and a reference voltage at a reference voltage node (labeled “vref”). As shown, an enable transistor MN5_EN (e.g., an lvt device) may be coupled in series with the transistor MN5 on the tail current path 382 to enable or disable the tail current source formed by transistor MN5 using the biasen signal.

The transistors MN5 and MN6 may sink a current from a node 306 coupled to sources of NMOS input transistors MN1, MN2, MN3, and MN4 of the amplifier 308. The transistors MN1, MN2, MN3, MN4 are part of respective input transistor paths 362, 364, 360, 366. As shown, the input transistor path 360 may be in parallel with the input transistor path 362, and the input transistor path 364 may be in parallel with the input transistor path 366. The input transistors MN3 and MN4 may be super-low voltage threshold (slvt) devices. As used herein, an slvt device or transistor generally refers to a transistor with a lower threshold voltage than an lvt device or transistor. The transistors MN1 and MN2 may be lvt devices. The drains of transistors MN1, MN3_EN are coupled to a negative output (outn) node of the amplifier 308.

The gates of the transistors MN1, MN3 may be coupled to the input node, and the gates of the transistors MN2, MN4 may be coupled to the vref node. The drain of transistor MN3 may be coupled to the drain of the transistor MN1 through an NMOS enable transistor MN3_EN on the input transistor path 360, which may be an slvt device. The gate of the transistor MN3_EN may be driven by a biasenb signal to enable or disable the path 360 including the input transistor MN3. The biasenb signal may be complementary to the biasen signal. Similarly, the drain of transistor MN4 may be coupled to the drain of the transistor MN2 through an NMOS enable transistor MN4_EN on the input transistor path 366, which may be an slvt device. The gate of the transistor MN4_EN may be driven by the biasenb signal to enable or disable the path 366 including the input transistor MN4. The drains of transistors MN2, MN4_EN are coupled to a positive output (outp) node of the amplifier 308.

A resistive load path 376 between the outn node and vdda may include a resistive element (e.g., resistive load) R1 and an enable PMOS transistor MPEN1. The gate of the transistor MPEN1 may be driven by the biasenb signal to enable or disable the path 376 including the resistive element R1. Another resistive load path 374 between the outn node and vdda may include a resistive element (e.g., resistive load) R2 and an enable PMOS transistor MPEN2. The gate of the transistor MPEN2 may be driven by an enb signal which may be complementary to the en signal used to drive the gate of transistor MNEN. The transistor MPEN2 may be used to enable or disable the path 374 including the resistive element R2. Another resistive load path 370 between the outp node and vdda may include a resistive element (e.g., resistive load) R4 and an enable PMOS transistor MPEN4. The gate of the transistor MPEN4 may be driven by the biasenb signal to enable or disable the path 370 including the resistive element R4. Another resistive load path 372 between the outp node and vdda may include a resistive element (e.g., resistive load) R3 and an enable PMOS transistor MPEN3. The gate of the transistor MPEN3 may be driven by the enb signal. The transistor MPEN3 may be used to enable or disable the path 372 including the resistive element R3. As shown, the transistors MPEN1, MPEN2, MPEN3, MPEN4 may be rvt devices. The outp and outn nodes may be coupled to gates of input transistors MN8, MN9 of an amplifier 310 to generate the comp_out signal, as described in more detail herein.

The transistors MN6, MPEN2, MPEN3 remain turned on (e.g., regardless of operating mode) as long as the comparator 300 is enabled via the en signal provided to the gate of transistor MNEN. In certain aspects of the present disclosure, input transistors, a tail current source, and resistive load paths may be enabled or disabled based on a configured operating mode of the comparator. In a first mode of operation, the comparator 300 may support a lower input voltage and vref (e.g., 0.45×vddio as described with respect to FIG. 2) as compared to a second mode of operation. In the first mode of operation, the biasen signal may be set to logic low, and the biasenb signal may be set to logic high (e.g., vdda). Thus, the transistor MN5_EN may be turned off, disabling the current source formed by transistor MN5. By turning off MN5_EN, the tail current sunk from the node 306 may be reduced, resulting in the voltage at node 306 increasing to keep the tail transistor MN6 in saturation, as described in more detail herein.

In some aspects, in the first mode of operation, the transistors MN3_EN, MN4_EN are turned on, enabling the input transistor paths 360, 366 including the slvt input transistors MN3, MN4 (e.g., input pair), respectively. As a result, the voltage at node 306 may be increased to keep the transistor MN6 in saturation as described. The input transistors MN3, MN4 may be implemented as slvt devices as these transistors are turned on in the first mode of operation where a lower input and reference voltage level is to be supported. In some aspects, in the first mode of operation, the transistors MPEN1, MPEN4 may be turned off to turn off the resistive load paths 376, 370, respectively. In this case, the current from vdda may only flow through resistive elements R2 and R3 (e.g., since the paths including R1 and R4 are disabled), providing increased gain for the amplifier 308.

In the second mode of operation where the comparator 300 is to support a higher vref (e.g., 0.8×vddio as described with respect to FIG. 2) to be provided to the gate of input transistor MN2, the biasen signal may be set to logic high (e.g., vdda), and the biasenb signal may be set to logic low. Thus, the transistor MN5_EN may be turned on, resulting in increased tail current sunk from node 306. As a result, the voltage at node 306 may be decreased to maintain a high output impedance for input transistors MN1 and MN2 when a high gate voltage is present. In other words, the decrease of the voltage at node 306 at the sources of transistors MN1, MN2 results in increased drain-to-source voltages for the transistors MN1, MN2. The increased drain-to-source voltages allow the transistors MN1, MN2 to operate in proper operating conditions (to maintain high transconductance (gₘ)/channel conductance (g_{ds})).

In some aspects, in the second mode of operation, the transistors MN3_EN and MN4_EN are turned off to disable the paths 360, 366 with the slvt input transistors MN3, MN4. Turning off the paths 360, 366 with input transistors MN3, MN4 decreases the voltage at node 306 to operate the transistors MN1, MN2 in proper operating conditions (to maintain high gₘ/g_{ds}).

In some aspects, in the second mode of operation, the transistors MPEN1, MPEN4 are turned on. Thus, the resistive load path 376 with resistive element R1 and the resistive load path 370 with resistive element R4 are enabled in an attempt to prevent the voltage at the outp and outn nodes from decreasing in the presence of increased tail current. As a result, MN1 and MN2 may operate under proper conditions, maintaining a high gₘ/g_{ds} ratio.

As shown, the current mirror 304 includes another branch implemented using transistor MN10 which may be an lvt device. The transistor MN10 forms a tail current source for the amplifier 310 and is coupled to the sources of input transistors MN8, MN9. As described, the gates of the input transistors MN8, MN9 are coupled to the outp and outn nodes, respectively. The drain of transistor MN8 is coupled to a branch of a current mirror 320 formed via a PMOS transistor MP1 (e.g., an slvt device), where another branch of the current mirror 320 includes a PMOS transistor MP4 (e.g., an slvt device). The drain of the transistor MP4 may be coupled to an output (amp_out) node of the amplifier 310. Moreover, the drain of transistor MN9 is coupled to a branch of a current mirror 322 implemented via a PMOS transistor MP2 (e.g., an slvt device), where another branch of the current mirror 322 includes a PMOS transistor MP3 (e.g., an slvt device). The drain of transistor MP3 is coupled to a branch of a current mirror 324 implemented via an NMOS transistor MN11 (e.g., an lvt device), where another branch of the current mirror 324 includes an NMOS transistor MN12 (e.g., an lvt device) with a drain coupled to the amp_out node. As shown, the amp_out signal may be buffered via a buffer 330 to generate the comp_out signal.

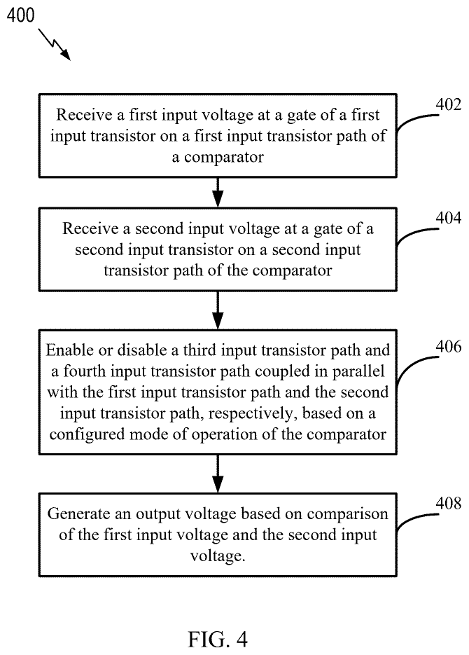

FIG. 4 is a flow diagram illustrating example operations 400 for voltage comparison. The operations 400 may be performed, for example, by a comparator such as the comparator 300 of FIG. 3.

At block 402, the comparator receives a first input voltage at a gate of a first input transistor (e.g., transistor MN1) on a first input transistor path (e.g., input transistor path 362) of the comparator. At block 404, the comparator receives a second input voltage at a gate of a second input transistor (e.g., transistor MN2) on a second input transistor path (e.g., input transistor path 364) of the comparator.

At block 406, the comparator enables or disables (e.g., controls enablement of) a third input transistor path (e.g., input transistor path 360) and a fourth input transistor path (e.g., input transistor path 366) coupled in parallel with the first input transistor path and the second input transistor path, respectively, based on a configuration mode of operation of the comparator. At block 408, the comparator may generate an output voltage (e.g., comp_out signal) based on comparison of the first input voltage and the second input voltage.

In some aspects, the third input transistor path includes a third input transistor (e.g., transistor MN3) in series with a first enable transistor (e.g., transistor MN3_EN). In some aspects, the fourth input transistor path includes a fourth input transistor (e.g., transistor MN4) in series with a second enable transistor (e.g., transistor MN4_EN). The comparator may enable or disable the third input transistor path and the fourth input transistor path by controlling the first enable transistor and the second enable transistor. In some aspects, the third input transistor and the fourth input transistor have a lower threshold voltage than the first input transistor and the second input transistor.

In some aspects, controlling the first enable transistor and the second enable transistor includes turning on the first enable transistor and the second enable transistor to enable the third input transistor path and the fourth input transistor path based on the configuration mode of operation being a first mode of operation. The comparator may turn off the first enable transistor and the second enable transistor to disable the third input transistor path and the fourth input transistor path based on the configuration mode of operation being a second mode of operation. The second input voltage may be a first reference voltage (e.g., 0.45×vdda) during the first mode of operation, and the second input voltage may be a second reference voltage (e.g., 0.8×vdda) during the second mode of operation, the second reference voltage being greater than the first reference voltage.

In some aspects, the comparator may sink, via a first tail current source (e.g., transistor MN6) on a first tail current path (e.g., tail current path 380), a first tail current from a node (e.g., node 306) coupled to the first input transistor path and the second input transistor path. The comparator may enable or disable a second tail current path (e.g., tail current path 382) coupled in parallel with the first tail current path based on the configuration mode of operation. In some aspects, the second tail current path includes a tail current path enable transistor (e.g., transistor MN5_EN) in series with a second tail current source (e.g., transistor MN5). Enabling or disabling the second tail current path may include controlling the tail current path enable transistor.

In some aspects, enabling or disabling the second tail current path includes turning off the tail current path enable transistor to disable the second tail current path during a first mode of operation of the comparator, the second input voltage being a first reference voltage (e.g., 0.45×vdda) during the first mode of operation. The comparator may enable the second tail current path by turning on the tail current path enable transistor during a second mode of operation of the comparator, the second input voltage being a second reference voltage (e.g., 0.8×vdda) during the second mode of operation, the second reference voltage being greater than the first reference voltage.

In some aspects, the comparator includes: (i) a first resistive load path (e.g., resistive load path 374) including a first resistive element (e.g., resistive element R2) coupled between a voltage rail (e.g., vdda) and the first input transistor path; and (ii) a second resistive load path (e.g., resistive load path 372) including a second resistive element (e.g., resistive element R3) coupled between the voltage rail and the second input transistor path.

In some aspects, the comparator may enable or disable a third resistive load path (e.g., resistive load path 374) including a third resistive element (e.g., resistive element R1) coupled between the voltage rail and the first input transistor path based on the configuration mode of operation of the comparator, the third resistive load path further including a first resistive load path enable transistor (e.g., transistor MPEN1) in series with the third resistive element. The comparator may enable or disable a fourth resistive load path (e.g., resistive load path 370) including a fourth resistive element coupled between the voltage rail and the second input transistor path based on the configuration mode of operation of the comparator, the fourth resistive load path further including a second resistive load path enable transistor (e.g., transistor MPEN4) in series with the fourth resistive element.

In some aspects, the comparator may enable or disable the third resistive load path and the fourth resistive load path by turning off the first resistive load path enable transistor and the second resistive load path enable transistor to disable the third resistive load path and the fourth resistive load path, respectively, during a first mode of operation of the comparator, the second input voltage including a first reference voltage (e.g., 0.45×vdda) during the first mode of operation. The comparator may turn on the first resistive load path enable transistor and the second resistive load path enable transistor to enable the third resistive load path and the fourth resistive load path, respectively, during a second mode of operation of the comparator, the second input voltage including a second reference voltage (e.g., 0.8×vdda) during the second mode of operation, the second reference voltage being greater than the first reference voltage.

### Example Aspects

In addition to the various aspects described above, specific combinations of aspects are within the scope of the disclosure, some of which are detailed below:
Aspect 1: A comparator, comprising: a first input transistor path including a first input transistor with a gate coupled to a first input node of the comparator; a second input transistor path including a second input transistor with a gate coupled to a second input node of the comparator; a third input transistor path in parallel with the first input transistor path and including a third input transistor with a gate coupled to the first input node; and a fourth input transistor path in parallel with the second input transistor path and including a fourth input transistor with a gate coupled to the second input node.
Aspect 2: The comparator of Aspect 1, wherein: the third input transistor path further comprises a first enable transistor; and the fourth input transistor path further comprises a second enable transistor.
Aspect 3: The comparator of Aspect 1 or 2, further comprising: a first tail current path including a first tail current source coupled to the first input transistor path and the second input transistor path; and a second tail current path including a second tail current source, the second tail current path being coupled in parallel with the first tail current path.
Aspect 4: The comparator of Aspect 3, wherein the second tail current path includes a tail current path enable transistor in series with the second tail current source.
Aspect 5: The comparator of Aspect 4, wherein: the tail current path enable transistor is configured to be turned off during a first mode of operation of the comparator, the gate of the second input transistor being configured to receive a first reference voltage during the first mode of operation; and the tail current path enable transistor is configured to be turned on during a second mode of operation of the comparator, the gate of the second input transistor being configured to receive a second reference voltage during the second mode of operation, the second reference voltage being greater than the first reference voltage.
Aspect 6: The comparator according to any of Aspects 1-5, further comprising: a first resistive load path including a first resistive element coupled between a voltage rail and the first input transistor path; and a second resistive load path including a second resistive element coupled between the voltage rail and the second input transistor path.
Aspect 7: The comparator of Aspect 6, further comprising: a third resistive load path including a third resistive element coupled between the voltage rail and the first input transistor path, the third resistive load path further including a first resistive load path enable transistor in series with the third resistive element; and a fourth resistive load path including a fourth resistive element coupled between the voltage rail and the second input transistor path, the fourth resistive load path further including a second resistive load path enable transistor in series with the fourth resistive element.
Aspect 8: The comparator of Aspect 7, wherein: the first resistive load path enable transistor and the second resistive load path enable transistor are configured to be turned off during a first mode of operation of the comparator, the gate of the second input transistor being configured to receive a first reference voltage during the first mode of operation; and the first resistive load path enable transistor and the second resistive load path enable transistor are configured to be turned on during a second mode of operation of the comparator, the gate of the second input transistor being configured to receive a second reference voltage during the second mode of operation, the second reference voltage being greater than the first reference voltage.
Aspect 9: The comparator according to any of Aspects 1-8, wherein the third input transistor and the fourth input transistor have a lower threshold voltage than the first input transistor and the second input transistor.
Aspect 10: The comparator according to any of Aspects 1-9, wherein the second input node comprises a reference voltage node of the comparator.
Aspect 11: The comparator according to any of Aspects 1-10, wherein: the third input transistor path further comprises a first enable transistor and the fourth input transistor path further comprises a second enable transistor; the first enable transistor and the second enable transistor are configured to be turned on during a first mode of operation of the comparator, the gate of the second input transistor being configured to receive a first reference voltage during the first mode of operation; and the first enable transistor and the second enable transistor are configured to be turned off during a second mode of operation of the comparator, the gate of the second input transistor being configured to receive a second reference voltage during the second mode of operation, the second reference voltage being greater than the first reference voltage.
Aspect 12: A method for voltage comparison, comprising: receiving a first input voltage at a gate of a first input transistor on a first input transistor path of a comparator; receiving a second input voltage at a gate of a second input transistor on a second input transistor path of the comparator; enabling or disabling a third input transistor path and a fourth input transistor path coupled in parallel with the first input transistor path and the second input transistor path, respectively, based on a configuration mode of operation of the comparator; and generating an output voltage based on comparison of the first input voltage and the second input voltage.
Aspect 13: The method of Aspect 12, wherein: the third input transistor path includes a third input transistor in series with a first enable transistor; the fourth input transistor path includes a fourth input transistor in series with a second enable transistor; and enabling or disabling the third input transistor path and the fourth input transistor path includes controlling the first enable transistor and the second enable transistor.
Aspect 14: The method of Aspect 13, wherein the third input transistor and the fourth input transistor have a lower threshold voltage than the first input transistor and the second input transistor.
Aspect 15: The method of Aspect 13 or 14, wherein: controlling the first enable transistor and the second enable transistor includes turning on the first enable transistor and the second enable transistor to enable the third input transistor path and the fourth input transistor path based on the configuration mode of operation being a first mode of operation; and the method further comprises turning off the first enable transistor and the second enable transistor to disable the third input transistor path and the fourth input transistor path based on the configuration mode of operation being a second mode of operation.
Aspect 16: The method of Aspect 15, wherein: the second input voltage comprises a first reference voltage during the first mode of operation; and the second input voltage comprises a second reference voltage during the second mode of operation, the second reference voltage being greater than the first reference voltage.
Aspect 17: The method according to any of Aspects 12-16, further comprising: sinking, via a first tail current source on a first tail current path, a first tail current from a node coupled to the first input transistor path and the second input transistor path; and enabling or disabling a second tail current path coupled in parallel with the first tail current path based on the configuration mode of operation.
Aspect 18: The method of Aspect 17, wherein the second tail current path includes a tail current path enable transistor in series with a second tail current source, wherein enabling or disabling the second tail current path includes controlling the tail current path enable transistor.
Aspect 19: The method of Aspect 18, wherein: enabling or disabling the second tail current path includes turning off the tail current path enable transistor to disable the second tail current path during a first mode of operation of the comparator, the second input voltage including a first reference voltage during the first mode of operation; and the method further comprises enabling the second tail current path by turning on the tail current path enable transistor during a second mode of operation of the comparator, the second input voltage including a second reference voltage during the second mode of operation, the second reference voltage being greater than the first reference voltage.
Aspect 20: The method according to any of Aspects 12-19, wherein the comparator further comprises: a first resistive load path including a first resistive element coupled between a voltage rail and the first input transistor path; and a second resistive load path including a second resistive element coupled between the voltage rail and the second input transistor path.
Aspect 21: The method of Aspect 20, further comprising: enabling or disabling a third resistive load path including a third resistive element coupled between the voltage rail and the first input transistor path based on the configuration mode of operation of the comparator, the third resistive load path further including a first resistive load path enable transistor in series with the third resistive element; and enabling or disabling a fourth resistive load path including a fourth resistive element coupled between the voltage rail and the second input transistor path based on the configuration mode of operation of the comparator, the fourth resistive load path further including a second resistive load path enable transistor in series with the fourth resistive element.
Aspect 22: The method of Aspect 21, wherein: enabling or disabling the third resistive load path and the fourth resistive load path including turning off the first resistive load path enable transistor and the second resistive load path enable transistor to disable the third resistive load path and the fourth resistive load path, respectively, during a first mode of operation of the comparator, the second input voltage including a first reference voltage during the first mode of operation; and the method further comprises turning on the first resistive load path enable transistor and the second resistive load path enable transistor to enable the third resistive load path and the fourth resistive load path, respectively, during a second mode of operation of the comparator, the second input voltage including a second reference voltage during the second mode of operation, the second reference voltage being greater than the first reference voltage.
Aspect 23: A calibration circuit, comprising: a first multiplexer with a first input coupled to a first input node of the calibration circuit and a second input coupled to a second input node of the calibration circuit; a second multiplexer with a first input coupled to a first reference voltage node of the calibration circuit and a second input coupled to a second reference voltage node of the calibration circuit; and a comparator comprising: a first input transistor path including a first input transistor with a gate coupled to an output of the first multiplexer; a second input transistor path including a second input transistor with a gate coupled to an output of the second multiplexer; a third input transistor path in parallel with the first input transistor path and including a third input transistor with a gate coupled to the first input node; and a fourth input transistor path in parallel with the second input transistor path and including a fourth input transistor with a gate coupled to the second input node.

### Additional Considerations

The various operations of methods described above may be performed by any suitable means capable of performing the corresponding functions. The means may include various hardware and/or software component(s) and/or module(s), including, but not limited to a circuit, an application-specific integrated circuit (ASIC), or a processor. Generally, where there are operations illustrated in figures, those operations may have corresponding counterpart means-plus-function components with similar numbering.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes, and variations may be made in the arrangement, operation, and details of the methods and apparatus described above without departing from the scope of the claims.

What is claimed is:

1. A comparator, comprising:
a first input transistor path including a first input transistor with a gate coupled to a first input node of the comparator;
a second input transistor path including a second input transistor with a gate coupled to a second input node of the comparator;
a third input transistor path in parallel with the first input transistor path and including a third input transistor with a gate coupled to the first input node; and
a fourth input transistor path in parallel with the second input transistor path and including a fourth input transistor with a gate coupled to the second input node.

2. The comparator of claim 1, wherein:
the third input transistor path further comprises a first enable transistor; and
the fourth input transistor path further comprises a second enable transistor.

3. The comparator of claim 1, further comprising:
a first tail current path including a first tail current source coupled to the first input transistor path and the second input transistor path; and
a second tail current path including a second tail current source, the second tail current path being coupled in parallel with the first tail current path.

4. The comparator of claim 3, wherein the second tail current path includes a tail current path enable transistor in series with the second tail current source.

5. The comparator of claim 4, wherein:
the tail current path enable transistor is configured to be turned off during a first mode of operation of the comparator, the gate of the second input transistor being configured to receive a first reference voltage during the first mode of operation; and
the tail current path enable transistor is configured to be turned on during a second mode of operation of the comparator, the gate of the second input transistor being configured to receive a second reference voltage during the second mode of operation, the second reference voltage being greater than the first reference voltage.

6. The comparator of claim 1, further comprising:
a first resistive load path including a first resistive element coupled between a voltage rail and the first input transistor path; and
a second resistive load path including a second resistive element coupled between the voltage rail and the second input transistor path.

7. The comparator of claim 6, further comprising:
a third resistive load path including a third resistive element coupled between the voltage rail and the first input transistor path, the third resistive load path further including a first resistive load path enable transistor in series with the third resistive element; and
a fourth resistive load path including a fourth resistive element coupled between the voltage rail and the second input transistor path, the fourth resistive load path further including a second resistive load path enable transistor in series with the fourth resistive element.

8. The comparator of claim 7, wherein:
the first resistive load path enable transistor and the second resistive load path enable transistor are configured to be turned off during a first mode of operation of the comparator, the gate of the second input transistor being configured to receive a first reference voltage during the first mode of operation; and
the first resistive load path enable transistor and the second resistive load path enable transistor are configured to be turned on during a second mode of operation of the comparator, the gate of the second input transistor being configured to receive a second reference voltage during the second mode of operation, the second reference voltage being greater than the first reference voltage.

9. The comparator of claim 1, wherein the third input transistor and the fourth input transistor have a lower threshold voltage than the first input transistor and the second input transistor.

10. The comparator of claim 1, wherein the second input node comprises a reference voltage node of the comparator.

11. The comparator of claim 1, wherein:
the third input transistor path further comprises a first enable transistor and the fourth input transistor path further comprises a second enable transistor;
the first enable transistor and the second enable transistor are configured to be turned on during a first mode of operation of the comparator, the gate of the second input transistor being configured to receive a first reference voltage during the first mode of operation; and
the first enable transistor and the second enable transistor are configured to be turned off during a second mode of operation of the comparator, the gate of the second input transistor being configured to receive a second reference voltage during the second mode of operation, the second reference voltage being greater than the first reference voltage.

12. A method for voltage comparison, comprising:
receiving a first input voltage at a gate of a first input transistor on a first input transistor path of a comparator;
receiving a second input voltage at a gate of a second input transistor on a second input transistor path of the comparator;
enabling or disabling a third input transistor path and a fourth input transistor path coupled in parallel with the first input transistor path and the second input transistor path, respectively, based on a configuration mode of operation of the comparator; and
generating an output voltage based on comparison of the first input voltage and the second input voltage.

13. The method of claim 12, wherein:
the third input transistor path includes a third input transistor in series with a first enable transistor;
the fourth input transistor path includes a fourth input transistor in series with a second enable transistor; and
enabling or disabling the third input transistor path and the fourth input transistor path includes controlling the first enable transistor and the second enable transistor.

14. The method of claim 13, wherein the third input transistor and the fourth input transistor have a lower threshold voltage than the first input transistor and the second input transistor.

15. The method of claim 13, wherein:
controlling the first enable transistor and the second enable transistor includes turning on the first enable transistor and the second enable transistor to enable the third input transistor path and the fourth input transistor path based on the configuration mode of operation being a first mode of operation; and
the method further comprises turning off the first enable transistor and the second enable transistor to disable the third input transistor path and the fourth input transistor path based on the configuration mode of operation being a second mode of operation.

16. The method of claim 15, wherein:
the second input voltage comprises a first reference voltage during the first mode of operation; and
the second input voltage comprises a second reference voltage during the second mode of operation, the second reference voltage being greater than the first reference voltage.

17. The method of claim 12, further comprising:
sinking, via a first tail current source on a first tail current path, a first tail current from a node coupled to the first input transistor path and the second input transistor path; and
enabling or disabling a second tail current path coupled in parallel with the first tail current path based on the configuration mode of operation.

18. The method of claim 17, wherein the second tail current path includes a tail current path enable transistor in series with a second tail current source, wherein enabling or disabling the second tail current path includes controlling the tail current path enable transistor.

19. The method of claim 18, wherein:
enabling or disabling the second tail current path includes turning off the tail current path enable transistor to disable the second tail current path during a first mode of operation of the comparator, the second input voltage including a first reference voltage during the first mode of operation; and
the method further comprises enabling the second tail current path by turning on the tail current path enable transistor during a second mode of operation of the comparator, the second input voltage including a second reference voltage during the second mode of operation, the second reference voltage being greater than the first reference voltage.

20. A calibration circuit, comprising:
a first multiplexer with a first input coupled to a first input node of the calibration circuit and a second input coupled to a second input node of the calibration circuit;
a second multiplexer with a first input coupled to a first reference voltage node of the calibration circuit and a second input coupled to a second reference voltage node of the calibration circuit; and
a comparator comprising:
a first input transistor path including a first input transistor with a gate coupled to an output of the first multiplexer;
a second input transistor path including a second input transistor with a gate coupled to an output of the second multiplexer;
a third input transistor path in parallel with the first input transistor path and including a third input transistor with a gate coupled to the first input node; and
a fourth input transistor path in parallel with the second input transistor path and including a fourth input transistor with a gate coupled to the second input node.
